(19) United States
(12) Patent Application Publication
(10) Pub. No.: US 2026/0327492 A1
(43) Pub. Date: Oct. 22, 2026

(54) ETCHING COMPOSITIONS FOR COPPER

(71) Applicant: Fujifilm Electronic Materials U.S.A., Inc., N. Kingstown, RI (US)

(72) Inventors: Dmitry Dinega, Mesa, AZ (US); William A. Wojtczak, Mesa, AZ (US)

(21) Appl. No.: 19/650,422

(22) Filed: Apr. 17, 2026

Related U.S. Application Data
(60) Provisional application No. 63/790,786, filed on Apr. 18, 2025.

(51) Int. Cl. C09K 13/06; H10P 50/66; H10P 70/00

(52) U.S. Cl. CPC C09K 13/06; H10P 50/667; H10P 70/27

(57) ABSTRACT

The present disclosure is directed to etching compositions that are useful for, e.g., selectively removing Cu from a semiconductor substrate as an intermediate step in a multistep semiconductor manufacturing process.

### CROSS REFERENCE TO RELATED APPLICATION

The present application claims priority to U.S. Provisional Application Ser. No. 63/790,786, filed on Apr. 18, 2025, the contents of which are hereby incorporated by reference in their entirety.

### FIELD OF THE DISCLOSURE

The present disclosure relates to etching compositions and processes of using etching compositions. In particular, the present disclosure relates to etching compositions that can selectively etch copper in the presence of other exposed or underlying materials, such as polybenzoxazole layers, polyimide layers, organic passivation layers, titanium barrier layers, silicon nitride layers, glass substrates, SnAg layers, nickel layers, and silicon layers.

### BACKGROUND OF THE DISCLOSURE

The semiconductor industry is rapidly decreasing the dimensions and increasing the density of electronic circuitry and electronic components in microelectronic devices, silicon chips, liquid crystal displays, MEMS (Micro Electro Mechanical Systems), printed wiring boards, and the like. The integrated circuits within them are being layered or stacked with constantly decreasing thicknesses of the insulating layer between each circuitry layer and smaller and smaller feature sizes. As the feature sizes have shrunk, patterns have become smaller, and device performance parameters tighter and more robust. As a result, various issues which heretofore could be tolerated, can no longer be tolerated or have become more of an issue due to the smaller feature size.

To create advanced integrated circuits, copper metallization is integral in the chip interconnect, packaging, and circuit board manufacturing processes. The copper is typically deposited by electroplating processes. The use of photoresist patterning and copper wet etchants allows removal of copper in specific areas to create various conductive features. One such feature, in the packaging process, is the solder bump. The copper solder bump connects a chip's package to a printed circuit board (PCB).

### SUMMARY OF THE DISCLOSURE

The present disclosure relates to compositions and processes for selectively etching Cu in the presence of other exposed or underlying materials, such as polybenzoxazole layers, polyimide layers, organic passivation layers, titanium barrier layers, silicon nitride layers, glass substrates, SnAg layers, nickel layers, and silicon layers.

In some embodiments, there are provided etching compositions comprising: at least one organic acid, at least one quaternary ammonium salt, wherein each quaternary ammonium salt is in an amount of from about 5 ppm (parts per million) to about 25 ppm; and water, wherein the water is present in the composition in an amount of at least about 80 wt %.

In some embodiments, the at least one organic acid is in an amount of from about 5 wt % to about 15 wt % of the composition. In some embodiments, the at least one organic acid comprises acetic acid, propionic acid, butyric acid, or isobutyric acid. In some embodiments, the at least one organic acid comprises acetic acid.

In some embodiments, the at least one quaternary ammonium salt is a quaternary ammonium halide. In some embodiments, the at least one quaternary ammonium salt is a quaternary ammonium chloride. In some embodiments, there are at least two quaternary ammonium salts. In some embodiments, the at least two quaternary ammonium salts are benzalkonium chloride or benzethonium chloride.

In some embodiments, the compositions of the disclosure further comprise at least one oxidizing agent. In some embodiments, the at least one oxidizing agent comprises hydrogen peroxide or peracetic acid.

In some embodiments, the water is present in an amount of at least about 90 wt %.

In some embodiments, the composition has a pH of from about 2 to about 4.

In other embodiments of the disclosure there are provided methods, comprising: contacting a semiconductor substrate containing a Cu film with a composition of the disclosure to substantially remove the Cu film. In some embodiments, the methods further comprise rinsing the semiconductor substrate with a rinse solvent after the contacting step. In some embodiments, the methods further comprise drying the semiconductor substrate after the rinsing step.

In some embodiments, the methods of the disclosure do not substantially remove polybenzoxazole layers, polyimide layers, organic passivation layers, titanium barrier layers, silicon nitride layers, glass substrates, SnAg layers, nickel layers, and silicon layers.

In some embodiments, there are provided articles formed by the methods of the disclosure. In some embodiments, the articles are semiconductor devices. In some embodiments, the semiconductor devices are integrated circuits.

### DETAILED DESCRIPTION OF THE DISCLOSURE

As defined herein, unless otherwise noted, all percentages expressed should be understood to be percentages by weight to the total weight of the composition. Unless otherwise noted, ambient temperature is defined to be between about 16 and about 27 degrees Celsius (° C).

In general, the disclosure features compositions useful for etching Cu layers in the presence of other materials commonly found on substrates, for example, semiconductor substrates. The compositions include at least one organic acid; at least one quaternary ammonium salt, wherein each quaternary ammonium salt is in an amount of from about 5 ppm to about 25 ppm; and water, wherein the water is present in the composition in an amount of at least about 80 wt %.

The compositions of this disclosure can include at least one (e.g., two, three, or four) organic acid suitable for use in microelectronic applications. Organic acids contemplated for use in the compositions of the disclosure are not particularly limited, and can include, for example, acetic acid, propionic acid, butyric acid, isobutyric acid, and the like. In some embodiments, the organic acid is acetic acid.

In some embodiments, the at least one organic acid is in an amount of at least about 5 wt % (e.g., at least about 6 wt %, at least about 7 wt %, or at least about 8 wt %) to at most about 15 wt % (e.g., at most about 13 wt %, at most about 12 wt %, at most about 10 wt %, or at most about 9 wt %) of the compositions of this disclosure. Without wishing to be bound by theory, it is believed that organic acid can facilitate and enhance the removal of Cu on a semiconductor substrate during the etching process.

The etching composition of this disclosure can include at least one (e.g., two, three, or four) quaternary ammonium salts suitable for use in microelectronic applications. Quaternary ammonium salts contemplated for use in the compositions of the disclosure are not particularly limited. In some embodiments, the quaternary ammonium salts are quaternary ammonium halides. In some embodiments, the quaternary ammonium salts are quaternary ammonium chlorides. Examples of suitable quaternary ammonium salts include, but are not limited to, benzalkonium chloride, benzethonium chloride, and the like.

In some embodiments, the quaternary ammonium salt(s) can be present independently from at least about 5 ppm (e.g., at least about 6 ppm, at least about 7 ppm, at least about 8 ppm, at least about 9 ppm, or at least about 10 ppm) to at most about 25 ppm (e.g., at most about 24 ppm, at most about 23 ppm, at most about 22 ppm, or at most about 20 ppm) of the composition of this disclosure. Without wishing to be bound by theory, it is believed that the quaternary ammonium halide can facilitate and enhance the removal of Cu on a semiconductor substrate.

In some embodiments of the disclosure, the compositions further comprise at least one (e.g., two, three, or four) oxidizing agent suitable for use in microelectronic applications. Examples of suitable oxidizing agents include, but are not limited to, oxidizing acids or salts thereof (e.g., nitric acid, permanganic acid, or potassium permanganate), peroxides (e.g., hydrogen peroxide, dialkylperoxides, urea hydrogen peroxide), persulfonic acid (e.g., hexafluoropropanepersulfonic acid, methanepersulfonic acid, trifluoromethanepersulfonic acid, or p-toluenepersulfonic acid) and salts thereof, ozone, peroxycarboxylic acids (e.g., peracetic acid) and salts thereof, perphosphoric acid and salts thereof, persulfuric acid and salts thereof (e.g., ammonium persulfate or tetramethylammonium persulfate), perchloric acid and salts thereof (e.g., ammonium perchlorate, sodium perchlorate, or tetramethylammonium perchlorate), and periodic acid and salts thereof (e.g., periodic acid, ammonium periodate, or tetramethylammonium periodate). These oxidizing agents can be used singly or in combination.

In some embodiments, the at least one oxidizing agent can be from at least about 5 percent by weight (e.g., at least about 6 percent by weight, at least about 7 percent by weight, at least about 8 percent by weight, at least about 9 percent by weight, at least about 10 percent by weight, at least about 11 percent by weight, at least about 13 percent by weight, or at least about 15 percent by weight) to at most about 20 percent by weight (e.g., at most about 18 percent by weight, at most about 16 percent by weight, at most about 15 percent by weight, at most about 14 percent by weight, at most about 12 percent by weight, or at most about 10 percent by weight) of the etching composition of this disclosure. Without wishing to be bound by theory, it is believed that the oxidizing agent can facilitate and enhance the removal of Cu on a semiconductor substrate.

In general, the etching composition of this disclosure can include water as a solvent. In some embodiments, the water can be de-ionized and ultra-pure, contain no organic contaminants and have a minimum resistivity of about 4 to about 17 mega Ohms, or at least about 17 mega Ohms. In some embodiments, the water is in an amount of from at least about 80 wt % (e.g., at least about 81 wt %, at least about 82 wt %, at least about 83 wt %, at least about 84 wt %, at least about 85 wt %, at least about 86 wt %, at least about 87 wt %, or at least about 88 wt %) to at most about 95 wt % (e.g., at most about 94 wt %, at most about 93 wt %, at most about 92 wt %, at most about 91 wt %, or at most about 90 wt %) of the etching composition.

In some embodiments, the etching composition of this disclosure can further include at least one (e.g., two, three, or four) organic solvent. In some embodiments, the at least one organic solvent can include an alcohol or an alkylene glycol ether. Examples of suitable organic solvents include propylene glycol, hexylene glycol, 1,3-propanediol, ethylene glycol butyl ether, and 3-methoxy-3-methyl-1-butanol. In some embodiments, the at least one organic solvent can be from at least about 10 wt % (e.g., at least about 15 wt %, at least about 20 wt %, at least about 25 wt %, at least about 30 wt %, or at least about 35 wt %) to at most about 40 wt % (e.g., at most about 35 wt %, at most about 30 wt %, at most about 25 wt %, at most about 20 wt %, or at most about 15 wt %) of the etching composition.

In some embodiments, the etching composition of this disclosure can have a pH of at least about 2 (e.g., at least about 2.2, at least about 2.4, at least about 2.5, at least about 2.6, at least about 2.8, or at least about 2.9) and/or at most about 4 (e.g., at most about 3.8, at most about 3.6, at most about 3.5, at most about 3.4, at most about 3.2, at most about 3.1, or at most about 3.0).

In addition, in some embodiments, the etching composition of the present disclosure may contain additives such as, pH adjusting agents, corrosion inhibitors, surfactants, additional organic solvents, biocides, and defoaming agents as optional components. Examples of suitable additives include alcohols (e.g., polyvinyl alcohol), organic acids (e.g., iminodiacetic acid, malonic acid, oxalic acid, succinic acid, and malic acid), and inorganic acids (e.g., boric acid). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants may be cationic, anionic, nonionic or amphoteric.

In some embodiments, the etching compositions of the present disclosure may specifically exclude one or more of the additive components, in any combination, if more than one. Such components are selected from the group consisting of polymers, oxygen scavengers, quaternary ammonium salts (including quaternary ammonium hydroxides such as TMAH), amines, alkaline bases (such as NaOH, KOH, and LiOH), surfactants other than a defoamer, a defoamer, fluoride containing compounds, abrasives, silicates, hydroxycarboxylic acids containing more than two hydroxyl groups, carboxylic and polycarboxylic acids lacking amino groups, silanes (e.g., alkoxysilanes), cyclic compounds (e.g., azoles (such as diazoles, triazoles, or tetrazoles), triazines, and cyclic compounds containing at least two rings, such as substituted or unsubstituted naphthalenes, or substituted or unsubstituted biphenylethers), buffering agents, non-azole corrosion inhibitors, and metal salts (e.g., metal halides).

The etching composition of this disclosure can be prepared by simply mixing the components together, or may be prepared by blending two compositions in a kit. The first composition in the kit can be an aqueous solution of an oxidizing agent (e.g., H₂O₂). The second composition in the kit can contain the remaining components of the etching composition of this disclosure at predetermined ratios in a concentrated form such that the blending of the two compositions will yield a desired etching composition of the disclosure.

In other embodiments of the disclosure there are provided methods, comprising: contacting a semiconductor substrate containing a Cu film with a composition of the disclosure to substantially remove the Cu film. In some embodiments, the method does not substantially remove polybenzoxazole layers, polyimide layers, organic passivation layers, titanium barrier layers, silicon nitride layers, glass substrates, SnAg layers, nickel layers, and silicon layers. In some embodiments, the method does not substantially remove one or more of polybenzoxazole layers, polyimide layers, organic passivation layers, titanium barrier layers, silicon nitride layers, glass substrates, SnAg layers, nickel layers, or silicon layers.

In some embodiments, the methods further comprise rinsing the semiconductor substrate with a rinse solvent after the contacting step. In some embodiments, the methods further comprise drying the semiconductor substrate after the rinsing step.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates may also contain layers of interlayer dielectrics, polysilicon, silicon oxide, silicon nitride, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of about 85 °C (e.g., from about 20 °C to about 80 °C, from about 55 °C to about 65 °C, or from about 60 °C to about 65 °C). The etch rates of Cu increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 10 minutes (e.g., from about 1 minute to about 7 minutes, from about 1 minute to about 5 minutes, or from about 2 minutes to about 4 minutes). Etching times for a single wafer process can range from about 30 seconds to about 5 minutes (e.g., from about 30 seconds to about 4 minutes, from about 1 minute to about 3 minutes, or from about 1 minute to about 2 minutes).

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate and propylene glycol monomethyl ether acetate. Alternatively, or in addition, aqueous rinses with pH>8 (such as dilute aqueous ammonium hydroxide) can be employed. Examples of rinse solvents include, but are not limited to, dilute aqueous ammonium hydroxide, DI water, methanol, ethanol, and isopropyl alcohol. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16 °C and 27 °C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying or any combinations thereof. Drying times will be dependent on the specific method employed but are typically on the order of 30 seconds up to several minutes.

In some embodiments, the etching method described herein further includes forming a semiconductor device (e.g., an integrated circuit device such as a semiconductor chip) from the semiconductor substrate obtained by the method described above.

In further embodiments, it is understood that the compositions of the disclosure can be formulated as concentrates. In the practice of these embodiments, end users would add water and oxidizing agent to constitute ready-to-use formulations. In these embodiments, the concentration ranges of the components of the composition are as follows: organic acid 60-80 wt %; quaternary ammonium salts about 50-200 PPM; water about 20-40 wt %.

The present disclosure is illustrated in more detail with reference to the following examples, which are for illustrative purposes and should not be construed as limiting the scope of the present disclosure.

### EXAMPLES

Any percentages listed are by weight (wt %) unless otherwise specified. Controlled stirring during testing was done with a 1 inch stirring bar at 300 rpm unless otherwise noted.

### General Procedure 1

### Formulation Blending

Samples of etching compositions were prepared by adding, while stirring, to the calculated amount of the solvent the remaining components of the formulation. After a uniform solution was achieved, optional additives, if used, were added.

### General Procedure 2

### Materials and Methods

100 g of Formulation Example 1 (FE-1) was made in a PTFE (polytetrafluoroethylene) beaker by taking 7.89 g of glacial acetic acid and adding 58.48 g of deionized water, 8.03 g 31% H₂O₂ and then 17.66 g of 107 ppm stock solution of BACL (benzalkonium chloride) surfactant and 7.94 g of 107 ppm stock solution of BECL (benzethoium chloride) surfactant. The solution was heated to 25 °C and stirred at 200 rpm using a ½ inch stir bar. The copper, nickel, and titanium blanket film thicknesses were measured using a Filmetrics R50 resistance mapping tool using a film specific resistivity model. The thin non-metallic film thicknesses were measured by a Woollam M2000 ellipsometer with models employing suitable optical film parameters. Some of the blanket films, with thick organic layers, such as PBO, PI and OPLA were measured for thickness by x-section SEM at multiple sites and an average number reported. Surface roughness measurements were conducted on the as received and processed blanket films with a Rtec optical profilometer. The Ni—Cu undercut was measured by a Helios 5FX SEM using FIB methodology on the bump. It is desirable that the performance targets, other than copper etch rate, in Table 1 be met not just at the process time but also at 3× process time to ensure extended time material compatibility with the chemical. Typical process time is 50-70 sec to remove seed copper thicknesses of 3000-3600 Å.

The formulations in Table 1 can be formulated as concentrates that end users would add water and hydrogen peroxide to and constitute the ready to use formulations. For example, FE-1 would be formulated as a peroxide free concentrate of formula 68.67% glacial acetic acid, 164.8 ppm BACL and 73.8 ppm BECL and 31.3% water. This concentrate on addition of deionized water and 31% hydrogen peroxide in mass ratio of 10:70:7 would form FE-1.

TABLE 1

| | | | | *Cu | | | | | 1X/3X |
|---|---|---|---|---|---|---|---|---|---|
| Cu Etch | | | | Inhibit | *Cu | | Cu Etch | Cu Etch | Ni-Cu |
| Formulation | | Water, | Oxidizer, | or 1, | Inhibitor | Cu Etch | Time | Rate | Undercut |
| # | Acid, % | % | % | ppm | 2, ppm | Temp. °C | min | Å/min | nm** |
| FE-1 | Acetic Acid; | 89.62 | H₂O₂; | BACL; | BECL; | 25 | 1 | 3260 | 389/428 |
| | 7.89 | | 2.49 | 18.9 | 8.5 | | | | |
| FE-2 | Acetic Acid; | 89.62 | H₂O₂; | BACL; | | 25 | 1 | 3280 | 388/734 |
| | 7.89 | | 2.49 | 18.9 | | | | | |
| FE-3 | Acetic Acid; | 89.89 | H₂O₂; | | BECL; | 25 | 1 | 3210 | 410/594 |
| | 8 | | 2.11 | | 26.8 | | | | |

TABLE 2

| | FE-1 | FE-1 |
|---|---|---|
| Films | 1X | 3X |
| Cu, Å/min. (PVD) | 3195(68)*** | 2912(57) |
| Ni-Cu Undercut (Less | 389(58)/295(85) | 428(41)/489(45) |
| Dense/More Dense) | | |
| SnAg Solder | <2 | <2 |
| Ni (PVD) | ~0(2) | ~0(2) |
| Ti (PVD) | ~0(2) | ~0(2) |
| SiN (CVD)* | 0.7(0.2) | 0.4(0.2) |
| Org. Pass Layer (OPLA)** | ~0 | ~0 |
| Polybenzoxazole (PBO) (spin-on)** | ~0 | ~0 |
| Polyimide (PI) (spin-on)** | ~0 | ~0 |
| Si/Glass carriers | <5 | <5 |

As shown in Table 2, FE-1 exhibited relatively high Cu etch rates while minimizing the removal of exposed polybenzoxazole layers, polyimide layers, organic passivation layers, titanium barrier layers, silicon nitride layers, glass substrates, SnAg layers, nickel layers, and silicon layers on a semiconductor substrate during the etching process.

While the invention has been described in detail with reference to certain embodiments thereof, it will be understood that modifications and variations are within the spirit and scope of that which is described and claimed.

What is claimed is:

1. An etching composition, comprising:
at least one organic acid,
at least one quaternary ammonium salt, wherein each quaternary ammonium salt is independently in an amount of from about 5 ppm to about 25 ppm;
and
water, wherein the water is present in the composition in an amount of at least about 80 wt %.

2. The composition of claim 1, wherein the at least one organic acid is in an amount of from about 5 wt % to about 15 wt % of the composition.

3. The composition of claim 1, wherein the at least one organic acid comprises acetic acid, propionic acid, butyric acid, or isobutyric acid.

4. The composition of claim 1 wherein the at least one organic acid comprises acetic acid.

5. The composition of claim 1, wherein the at least one quaternary ammonium salt is quaternary ammonium halide.

6. The composition of claim 1, wherein the at least one quaternary ammonium salt is quaternary ammonium chloride.

7. The composition of claim 1, wherein the at least one quaternary ammonium salt is benzalkonium chloride or benzethonium chloride.

8. The composition of claim 1, wherein the composition comprises at least two quaternary ammonium salts.

9. The composition of claim 1 further comprising at least one oxidizing agent.

10. The composition of claim 1, wherein the at least one oxidizing agent comprises hydrogen peroxide or peracetic acid.

11. The composition of claim 1, wherein the water is present in an amount of at least about 90 wt %.

12. The composition of claim 1, wherein the composition has a pH of from about 2 to about 4.

13. A method, comprising:
contacting a semiconductor substrate containing a Cu film with a composition of claim 1 to substantially remove the Cu film.

14. The method of claim 13, further comprising rinsing the semiconductor substrate with a rinse solvent after the contacting step.

15. The method of claim 13, further comprising drying the semiconductor substrate after the rinsing step.

16. The method of claim 13, wherein the method does not substantially remove polybenzoxazole layers, polyimide layers, organic passivation layers, titanium barrier layers, silicon nitride layers, glass substrates, SnAg layers, nickel layers, and silicon layers.

17. An article formed by the method of claim 13, wherein the article is a semiconductor device.

18. The article of claim 17, wherein the semiconductor device is an integrated circuit.

19. An etching composition, comprising:
at least one organic acid,
at least two quaternary ammonium salts, wherein each quaternary ammonium salt is independently in an amount of from about 50 ppm to about 200 ppm;
and
water, wherein the water is present in the composition at least about 20 wt %.
